(19) United States
(12) Patent Application Publication
(10) Pub. No.: US 2010/0253381 A1
(43) Pub. Date: Oct. 7, 2010

(54) On-Chip Logic To Support In-Field Or Post-Tape-Out X-Masking In BIST Designs

(76) Inventors: Friedrich Hapke, Winsen (DE); Michael Wittke, Pinneberg (DE)

Correspondence Address: MENTOR GRAPHICS CORP.;PATENT GROUP, 8005 SW BOECKMAN ROAD, WILSONVILLE, OR, 97070-7777, US

(21) Appl. No.: 12/623,565

(22) Filed: Nov. 23, 2009

Related U.S. Application Data
(60) Provisional application No. 61/117,230, filed on Nov. 23, 2008.

(51) Int. Cl. G01R 31/26

(52) U.S. Cl. 324/765

(57) ABSTRACT

Techniques for masking unknown and irrelevant response values that may be produced by a BIST process. Masking circuitry is provided for selectively masking the response values obtained from a BIST process. The operation of the selective masking circuitry is controlled by a programmable mask circuitry controller that can be programmed after the integrated circuit has been manufactured. A user can analyze an integrated circuit after it has been manufactured to identify irrelevant and unknown data values in a BIST process. After the irrelevant and unknown data values have been identified, the user can program the programmable mask controller to have the selective masking circuitry mask the identified irrelevant and unknown data values.

### RELATED APPLICATIONS

This application claims priority to U.S. Provisional Patent Application No. 61/117,230, entitled “On-Chip Logic To Support In-Field Or Post-Tape-Out X-Masking In Logic-BIST Designs,” filed on Nov. 23, 2008, and naming Friedrich Hapke et al. as inventors, which application is incorporated entirely herein by reference.

### FIELD OF THE INVENTION

The present invention is directed to the selective masking of data generated by a scan-chain test of an integrated circuit device. Various implementations of the invention may be particularly useful for allowing a manufacturer to select the data to be masked after the integrated circuit device has been manufactured.

### BACKGROUND OF THE INVENTION

As integrated circuits continue to develop, they continue to have higher device densities and clocking rates. As a result, it requires ever-increasing numbers of test vectors to properly test them, which in turn requires larger and larger amounts of tester vector memory. Still further, manufacturing newer integrated circuits requires even more complex manufacturing techniques, with the corresponding increase in problems and costs related to the production of integrated circuits. To address these problems, and to allow for a self-test of integrated circuits in the field, a testing technique referred to as “built-in self-test” (BIST) is expected to be used more and more in the future.

With logic built-in self-test (LBIST), test circuits for testing the functional logic of an integrated circuit are added to the circuit's design. FIG. 1 illustrates the general configuration of an integrated circuit using LBIST. As seen in this figure, an integrated circuit 101 includes a test stimulus generator 103, a circuit-under-test (CUT) 105, and a test response evaluator 107. The integrated circuit 101 also includes a test control module 109, for controlling the operation of the test stimulus generator 103, the circuit-under-test (CUT) 105, and the test response evaluator 107. With this arrangement, the test stimulus generator 103 generates test stimuli that are applied to the circuit-under-test 105 through scan chains. The scan chains may be, for example, flip-flops in the circuit-under-test 105 that can be configured into serial shift registers during a test mode.

The self-test is performed by repeatedly shifting the generated test stimuli into the scan chains so that they are applied to the circuit-under-test 105, and operating the circuit-under-test 105 for a number of clock cycles in its functional application mode. Various techniques for generating efficient stimuli are well-known in the art. These include, for example, techniques for generating test stimuli for built-in self-test applications that improve the random testability of the circuit by state-of-the-art test points insertion (TPI), by a linear feedback shift register (LFSR) reseeding, by Bit-Flipping-Logic (see, for example, U.S. Pat. No. 6,789,221, issued Sep. 7, 2004, which patent is incorporated entirely herein by reference), or by a cycle-based stimuli generation (see, for example, European Patent Application No. 06126627.6, filed on Dec. 20, 2006, which application is incorporated entirely herein by reference as well).

The responses produced by the circuit-under-test 105 are captured by the scan chains, and relayed to the test response evaluator 107 where, for example, they are compacted on-chip using a compacting device, such as a multiple input shift register (MISR), to produce a compacted test signature. The compacted test signature can then be compared against a corresponding fault-free signature to determine if the integrated circuit has any of the faults tested for by the test stimuli. Depending upon the implementation, the compacted test signature can be compared with the fault-free signature on-chip, or after it has been exported off of the integrated circuit for comparison by, for example, automated test equipment.

While the responses produced by the circuit-under-test 105 include data bits that have known good circuit response data and which can detect a fault, the responses also may contain “unknown” data values (that is, data values that cannot be predicted because they may vary from test to test). If these unknown data values (referred to herein as “X values” or “Xs”) are compacted with the relevant data values, then the compacted test signature may not contain enough stable and predictable information to determine if the integrated circuit has one or more of the targeted faults. Accordingly, unknown data values must be purged from the responses before compaction. With conventional integrated circuits, however, there may be a large number of clock systems using high application frequencies. As a result, it is often not possible to precalculate all unknowns that may occur due to false path, clock skew, and inaccurate timing models for all of the library elements and layout wires used in the integrated circuit. With conventional testing techniques, a manufacturer instead will analyze a manufactured prototype of the integrated circuit to identify the unknown response values (Xs), and then create a new layout design of the integrated circuit to address the identified unknown response values. While this methodology provides for accurate testing, creating a new layout design with the associated masks for an integrated circuit is very expensive, and increases the time-to-market significantly.

### BRIEF SUMMARY OF THE INVENTION

Aspects of the invention relate to techniques for masking unknown response values that may be produced by a BIST process. According to various implementations of the invention, masking circuitry is provided for selectively masking the response values obtained from a BIST process. The operation of the selective masking circuitry then is controlled by a programmable mask circuitry controller that can be programmed after the integrated circuit has been manufactured. The programmable mask circuitry controller may be, for example, a fuse box or a Joint Test Action Group (JTAG) register (i.e., an IEEE 1149.1 compliant user register). With various implementations of the invention, a user will analyze the integrated circuit after it has been manufactured to identify the unknown data values. After the unknown data values have been identified, the user will then program the programmable mask controller to have the selective masking circuitry mask the identified unknown data values from the test signature.

### BRIEF DESCRIPTION OF THE DRAWINGS

FIG. 1 illustrates the general configuration of an integrated circuit using LBIST.

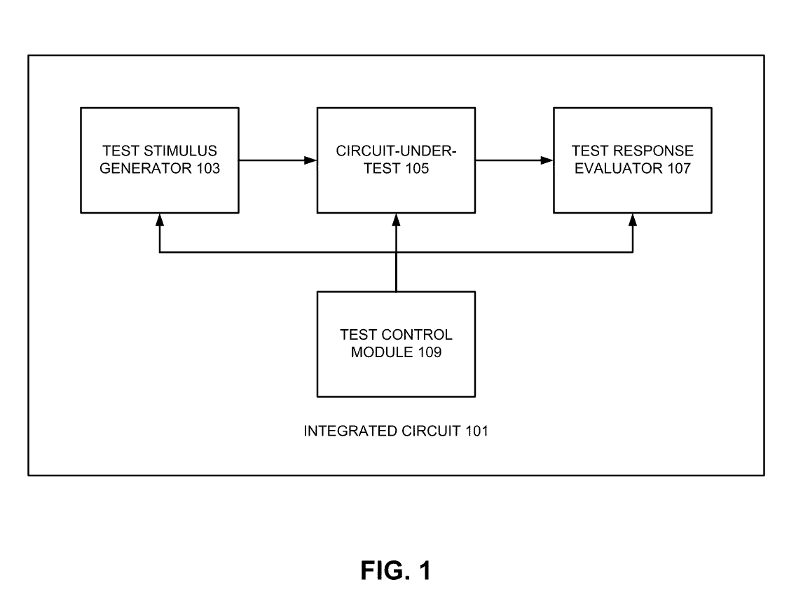

FIG. 2 illustrates a generic representation of a built-in self-test system that that can be used to perform post-tape-out or in-field masking of unknown test response values according to various embodiments of the invention.

FIG. 3 illustrates an example of a programmable mask circuitry controller configured to control the operation of selective masking circuitry according to various embodiments of the invention.

FIG. 4 illustrates another example of a programmable mask circuitry controller configured to control the operation of selective masking circuitry according to various embodiments of the invention.

### DETAILED DESCRIPTION OF THE INVENTION

### Built-In Self-Test System

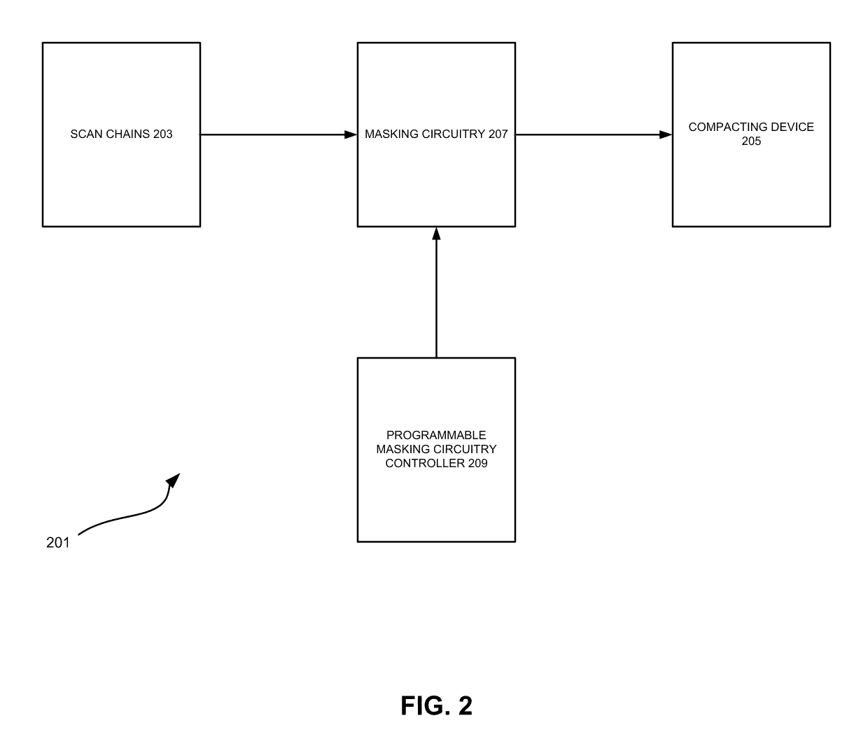

FIG. 2 illustrates a generic representation of a built-in self-test system that that can be used to perform post-tape-out or in-field masking of unknown test response values according to various implementations of the invention. As seen in this figure, the built-in self-test system 201 includes one or more scan chains 203 and a compacting device 205. The self-test system 201 also includes masking circuitry 207 and a programmable masking circuitry controller 209. With various examples of the invention, the scan chains 203 may operate in a conventional manner. That is, the scan chains 203 operate to apply test vectors to circuitry under test, and then capture the test response values produced by the tested circuitry. The masking circuitry 205 then serves to mask unknown values among the test response values.

More particularly, the masking circuitry 207 will mask specific unknown values in response to control information provided by the programmable masking circuitry controller 209. As will be discussed in more detail below, with various implementations of the invention, the programmable masking circuitry controller 209 can be programmed to have the masking circuitry 207 mask test response values output by specific scan chains 203, mask test response values output from one or more scan chains 203 for a specific number of cycles, or some combination of both. With various implementations of the invention, the programmable masking circuitry controller 209 can be programmed to determine while test response values will be masked after the integrated circuit has been manufactured. Because the unknown values can be identified and masked after the integrated circuit has been manufactured allows the self-test system 201 to be effectively employed post-tape-out or in the field.

Once the masking circuitry 207 has masked out the undesirable test response values, the compacting device 205 compacts the test response values that are passed (that is, the test response values that are not masked) by the masking circuitry 207. The compacting device 205 may be any type of compacting circuitry. For example, with various implementations of the invention, the compacting device 205 may be implemented using a MISR. It should be appreciated still other implementations of the invention can employ any desired type of compactor, including, e.g., a software-based compactor or a combination of two or more compactors.

### Fuse Box Programmable Mask Circuitry Controller

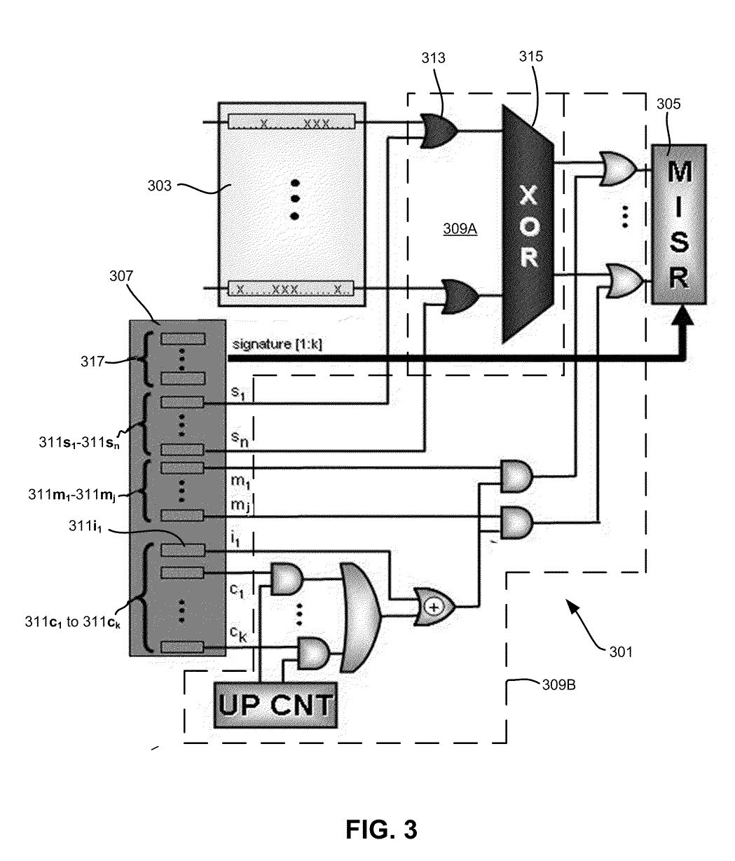

FIG. 3 shows a more detailed example of a self-test system 301 that can be used to perform post-tape-out or in-field masking of unknown test response values according to various implementations of the invention. As seen in this figure, the self-test system 301 includes a set of scan chains 303 and a MISR 305 for compacting the test response values provided by the scan chains 303. The self-test system 301 also includes a fuse box 307 and selective masking circuitry 309. As will be appreciated by those of ordinary skill in the art, the fuse box 307 serves as a programmable masking circuitry controller for controlling the operation of the selective masking circuitry 309. Further, the fuse box 307 can be programmed after the integrated circuit incorporating the self-test system 301 has been manufactured.

More particularly, the fuse box 307 outputs a certain number of control bits 311. If the initial output value on all outputs of the fuse box is a first value (e.g., a logical “0”), stimuli data can selectively be applied to the pins of the integrated circuit so that each output of the fuse box either permanently maintains its initial value or permanently maintains the opposite value (e.g., a logical “1”). Thus, it is possible for a user to selectively program the fuse box 307 so that each of the control bits 311 has either a logical value of “0” or a logical value of “1.” As previously noted, the fuse box 307 can be programmed after the integrated circuit has been manufactured. For example, a user may program the fuse box 307 during a production test for the integrated circuit. With conventional C-MOS processes, various examples of this type of fuse box are readily available and can be programmed within a few milliseconds.

The selective masking circuitry 309A, placed between the fuse box 307 and the MISR 305, can selectively mask out complete scan chains (such as, e.g., scan chain 303A). More particularly, the fuse box 307 can be programmed to determine the signal values of the control bits 311s₁ to 311sₙ (where n is the number of scan chains). Each of the control bits 311s₁ to 311sₙ is input to a masking gate 313 with the output values from a corresponding scan chain 303, and the results are then applied to a XOR compressor 315. Thus, the value selected for a control bit 311s will determine if the values for the corresponding scan chain 303 are masked or not masked.

It should be appreciated that, according to various implementations of the invention, a single control bit 311s can be used to mask a group of scan chains 303 instead of an individual scan chain 303, as illustrated in FIG. 3. For example, depending on the number of scan chains 303, the masking of complete chains 303 can be performed for individual scan chains (e.g., in case of less than 256 scan chains) by applying the output of only one scan chain 303 to a mask gate 313, as shown in FIG. 3. When there is a large number of scan chains 303 (e.g., in the case of 1000 scan chains), however, the outputs of multiple scan chains 303 can be applied to a single mask gate 313. (With these implementations, n represents the number of different groups of scan chains 303 to be masked.) It also should be appreciated that, while the masking gate 313 are located in front of the XOR compressor 315 in FIG. 3, with alternate implementations of the invention, the masking gates 313 can alternately or additionally be placed at the outputs of the XOR compressor 315. The decision as to where to place the masking gates 313 can be done on a per design base.

With various implementations of the invention, the masking circuitry 309B can alternately or additionally be used to mask out scan chains for selected test cycles. More particularly, scan chains 303 can be masked on a cyclic basis by programming the fuse box 307 to output specific values for the control bits 311m₁ to 311mⱼ, 311i₁, and 311c₁ to 311cₖ, where j is the number of MISR inputs and k is the number of bits in the cycle counter (not shown). As known to those of ordinary skill in the art, the cycle counter is reset with every normal cycle of the scan test, and is incremented with every shift cycle of the scan test, so it counts the shift cycles from 0 to 2^{k}−1.

As illustrated in FIG. 3, the cycle control bits 311c₁ to 311cₖ together with the up-counter device 317 and the inversion control bit i₁ allow for selection between many combinations for masking out cycles. The control bits 311m₁ to 311mₖ, allow for the selection of which group of scan chains 303 for which the cycle-based masking shall be performed. As will be appreciated by those of ordinary skill in the art, the logic configuration illustrated in FIG. 3 allows, for example, the masking of every 2, 4, or 8th cycle, or observation (i.e., not masking) of every 2, 4 or 8th cycle. The illustrated logic configuration also allows for the masking of 2 consecutive cycles, and then observation of the next 6 cycles. The inversion bit i₁ is used to invert the chosen masking (i.e., to determine whether the scan chain or chains 303 will be masked or not be masked). The illustrated logic configuration also allows, for example, masking out of the first half of all shift cycles and observation of the other half of the shift cycles, masking out of the first and third quarter of all shift cycles, etc. Accordingly, the logic configuration of various embodiments of the invention, while very small, allows a great deal of flexibility in what can be masked.

With some implementations, the programmable masking circuitry controller may also provide the fault-free signature to be compared with the test signature produced by the compactor. For example, as illustrated in FIG. 3, the fuse box 307 produces signature bits 317. Once the fault-free signature for the circuitry-under-test has been determined, the fuse box 307 can be programmed so that the signature bits 317 provide that fault-free signature to the MISR 305 (where the MISR 305 includes additional circuitry to compare the test signature with the fault free signature, or to a separate test response evaluator device if such a separate device is used to compare the test signature with the fault free signature).

### JTAG Register Programmable Mask Circuitry Controller

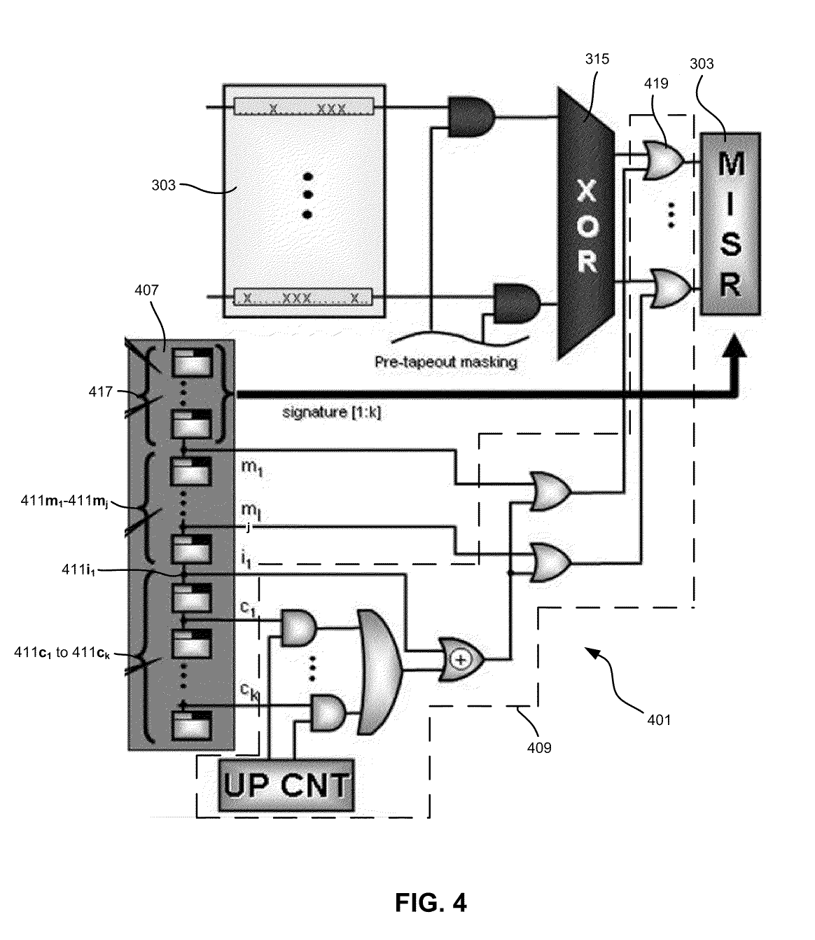

It should be appreciated that still other implementations of the invention may employ different programmable masking circuitry controllers and corresponding masking circuitry. For example, FIG. 4 illustrates an example of a self-test system 401 that employs a JTAG register 407 rather than a fuse box. As will be appreciated by those of ordinary skill in the art, a JTAG register typically occupies a smaller area on an integrated circuit than an equivalent fuse box.

As will be seen from this figure, the embodiment of the invention illustrated in FIG. 4 employs mask circuitry 409 having a different configuration than the masking circuitry 309 illustrated in FIG. 3. With this implementation, the mask gates 313 used to permanently mask specific scan chains (or scan chain groups) are omitted, and all of the masking is instead performed on a per-cycle basis. It should be appreciated, however, that various implementations of the embodiment shown in FIG. 4 can mask out scan chain groups instead of single scan chains via the control bits bits 411m₁ to 411mₖ. More particularly, the outputs of groups of scan chains can be output to each mask gate 419, so that the cycle masking will affect groups of scan chains 303 instead of individual scan chains 303. Of course, various embodiments of the invention may still employ any desired pre-tapeout masking devices placed in front of the XOR compressor 315. It is also possible to perform the cycle masking on selected scan chains, using additional control bits 311sᵢ to 311sₙ and corresponding masking circuitry as illustrated in FIG. 3. Overall, FIG. 4 is a low cost implementation of embodiments of the invention.

It should be appreciated that using a JTAG register as a programmable masking circuitry controller requires that the control bits be shifted into the register prior to the initiation of the self-test. This initial shifting can be done from a special-purpose test system, or from an application system in the case of an in-field self test.

With various implementations of the invention, an ATPG tool can be used to calculate the control bits that should be provided by the programmable masking circuitry controller during the self-test of the integrated circuit, to ensure that the masking circuitry masks unknown and irrelevant values so that a stable MISR signature is produced. Thus, with various embodiments of the invention, re-spins with new layout runs and creation of new mask sets are no longer required because the unknown values (Xs) can be masked out by programming a masking circuitry controller, such as a fuse box or JTAG register. Further, the register transfer language (RTL) code describing a self-test system according to various embodiments of the invention can be created very early in the design phase for an integrated circuit, independent of the logic of the circuit-under-test. Also, in the case of unforeseen unknowns, the ATPG tool only has to calculate the required control bit information to program the programmable masking circuitry controller, so that the unknowns are masked out as needed when the integrated circuit is tested after manufacture.

### CONCLUSION

While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims. For example, while specific implementations of the invention have been discussed with regard to logic built-in self-test techniques, it should be appreciated that implementations of the invention also may be employed with other types of built-in self-test techniques, such as memory built-in self-test (MBIST) techniques.

1. A method of masking unknown values in scan chains, comprising:
identifying unknown values in one or more scan chains of a manufactured integrated circuit device;
determining a masking operation of masking circuitry required to mask the identified unknown values; and
programming a programmable masking circuitry controller to cause the masking circuitry to implement the masking operation.

2. The method recited in claim 1, wherein
the programmable mask circuitry controller is a fuse box, and
programming the programmable mask circuitry controller includes burning fuses in the fuse box to fix output values of the fuse box such that the output values of the fuse box cause the masking circuitry to implement the masking operation.

3. The method recited in claim 1, wherein:
the programmable mask circuitry controller is a JTAG register, and
programming the programmable mask circuitry controller includes providing input data to the JTAG register to generate output values of the JTAG registers such that the output values of the JTAG register cause the masking circuitry to implement the masking operation.

4. A built-in self-test system on an integrated circuit device, comprising:
one or more scan chains configured to output test response values captured from circuitry on the integrated circuit device;
masking circuitry configured to selectively mask test response values output by the one or more scan chains; and
a programmable masking circuitry controller configured to control which test response values output from the one or more scan chains will be masked by the masking circuitry, the programmable masking circuitry controller being programmable after the integrated circuit has been manufactured.

5. The built-in self-test system recited in claim 4, further comprising a compacting device configured to compact test response values passed by the masking circuitry.

6. The built-in self-test system recited in claim 4, wherein the programmable masking circuitry controller is further configured to control for which test cycles and which group of test responses output from the one or more scan chains will be masked by the masking circuitry.

8. The built-in self-test system recited in claim 4, wherein the programmable masking circuitry controller is a fuse box.

9. The built-in self-test system recited in claim 4, wherein the programmable masking circuitry controller is a JTAG register.

10. A built-in self-test system on an integrated circuit, comprising:
means for outputting test response values captured from circuitry on an integrated circuit device;
means for selectively masking test response values output by the test response values outputting means; and
means for controlling which test response values output from the test response values outputting means will be masked by the means for selectively masking test response values, the means for controlling being programmable after the integrated circuit has been manufactured

11. The built-in self-test system recited in claim 10, further comprising:
compacting means for compacting test response values passed by the means for selectively masking test response values.

12. The method recited in claim 1, wherein the masking operation includes masking test response values output from a selection of scan chains in the one or more scan chains during a selection of test cycles.
